(19) United States
(12) Patent Application Publication
(10) Pub. No.: US 2023/0387910 A1
(43) Pub. Date: Nov. 30, 2023

(54) ELECTRONIC DEVICE

(71) Applicant: Innolux Corporation, Miaoli County (TW)

(72) Inventors: Kazuyuki Hashimoto, Miaoli County (TW); Hidetoshi Watanabe, Miaoli County (TW)

(73) Assignee: Innolux Corporation, Miaoli County (TW)

(21) Appl. No.: 18/173,081

(22) Filed: Feb. 23, 2023

Related U.S. Application Data
(60) Provisional application No. 63/345,036, filed on May 24, 2022.

(51) Int. Cl. H03K 17/56

(52) U.S. Cl. CPC H03K 17/56

(57) ABSTRACT

An electronic device is provided. The electronic device includes a tunable component and a first source follower circuit. The tunable component is electrically connected to a circuit node. The first source follower circuit is electrically connected to the circuit node. The first source follower circuit includes a first control terminal and a first terminal. The first control terminal is electrically connected to the first terminal, and the first control terminal is electrically connected to a data line through a first capacitor.

### CROSS-REFERENCE TO RELATED APPLICATION

This application claims the priority benefit of U.S. provisional application Ser. No. 63/345,036, filed on May 24, 2022. The entirety of the above-mentioned patent application is hereby incorporated by reference herein and made a part of this specification.

### BACKGROUND

### Technical Field

The disclosure relates a device, particularly, the disclosure relates to an electronic device.

### Description of Related Art

Antenna pixel circuit supplies a bias voltage to a varactor to control its permittivity with a storage capacitor (Cst). To keep the bias voltage within a specific range, the voltage needs to be re-stored (refresh) by data scan to compensate a voltage change by a leakage current of the varactor. However, there is a problem that higher leakage current requires higher refresh rates and/or larger storage capacitors to keep the bias voltage within a specific range, but which would be obstacles for commercialization.

### SUMMARY

The electronic device of the disclosure includes a tunable component and a first source follower circuit. The tunable component is electrically connected to a circuit node. The first source follower circuit is electrically connected to the circuit node, and includes a first control terminal and a first terminal. The first control terminal is electrically connected to the first terminal, and the first control terminal is electrically connected to a data line through a first capacitor.

Based on the above, according to the electronic device of the disclosure, the electronic device can effectively compensate the leakage current of the tunable component.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of an electronic device according to an embodiment of the disclosure.

FIG. 2 is a timing diagram of related voltages and signals according to the embodiment of FIG. 1 of the disclosure.

FIG. 3 is a schematic diagram of an electronic device according to an embodiment of the disclosure.

FIG. 4 is a timing diagram of related voltages and signals according to the embodiment of FIG. 3 of the disclosure.

FIG. 5 is a schematic diagram of an electronic device according to an embodiment of the disclosure.

FIG. 6 is a partial circuit schematic diagram of the electronic device according to another embodiment of FIG. 5 of the disclosure.

FIG. 7 is a schematic diagram of an electronic device according to an embodiment of the disclosure.

FIG. 8 is a timing diagram of related voltages and signals according to the embodiment of FIG. 7 of the disclosure.

FIG. 9 is a schematic diagram of an electronic device according to an embodiment of the disclosure.

FIG. 10 is a timing diagram of related voltages and signals according to the embodiment of FIG. 9 of the disclosure.

FIG. 11 is a schematic diagram of an electronic device according to an embodiment of the disclosure.

FIG. 12 is a partial circuit schematic diagram of the electronic device according to another embodiment of FIG. 11 of the disclosure.

### DESCRIPTION OF THE EMBODIMENTS

Reference will now be made in detail to the exemplary embodiments of the disclosure, examples of which are illustrated in the accompanying drawings. Whenever possible, the same reference numbers are used in the drawings and the description to refer to the same or like components.

Certain terms are used throughout the specification and appended claims of the disclosure to refer to specific components. Those skilled in the art should understand that electronic device manufacturers may refer to the same components by different names. This article does not intend to distinguish those components with the same function but different names. In the following description and rights request, the words such as “comprise” and “include” are open-ended terms, and should be explained as “including but not limited to . . . ”

The term “coupling (or electrically connection)” used throughout the whole specification of the present application (including the appended claims) may refer to any direct or indirect connection means. For example, if the text describes that a first device is coupled (or connected) to a second device, it should be interpreted that the first device may be directly connected to the second device, or the first device may be indirectly connected through other devices or certain connection means to be connected to the second device. The terms “first”, “second”, and similar terms mentioned throughout the whole specification of the present application (including the appended claims) are merely used to name discrete elements or to differentiate among different embodiments or ranges. Therefore, the terms should not be regarded as limiting an upper limit or a lower limit of the quantity of the elements and should not be used to limit the arrangement sequence of elements. In addition, wherever possible, elements/components/steps using the same reference numerals in the drawings and the embodiments represent the same or similar parts. Reference may be mutually made to related descriptions of elements/components/steps using the same reference numerals or using the same terms in different embodiments.

The electronic device of the disclosure may include an antenna pixel array circuit, and the antenna pixel array circuit may include M data signal lines, N scan signal lines, one or N bias signal lines, one or N reset signal lines, and an M×N antenna pixel array. M and N are positive integers. One pixel of the M×N antenna pixel array may include a tunable component and a constant voltage source circuit, and the tunable component may correspond to an antenna unit of one pixel of the antenna pixel array circuit. The M data signal lines are used to provide M data signals to the constant voltage source circuits of the pixels of the antenna pixel array. The N scan signal lines are used to provide N scan signals to the constant voltage source circuits of the pixels of the antenna pixel array. The one or N bias signal lines are used to provide one or N bias signals to the constant voltage source circuits of the pixels of the antenna pixel array. The one or N reset signal lines are used to provide one or N reset signals to the constant voltage source circuits of the pixels of the antenna pixel array. Each constant voltage source circuit is configured to drive the corresponding tunable component based on the corresponding data signal, the corresponding scan signal, the corresponding bias signal, and the corresponding reset signal. The tunable component of the disclosure may be, for example, a voltage-controlled device, and the voltage-controlled device may include, for example, a varactor, a resistor, an inductor or a capacitor. In the embodiment of the disclosure, the constant voltage source circuit of the disclosure may provide a voltage that can be efficiently restored (refreshed) through data scanning to compensate for the voltage change caused by the leakage current of the tunable component.

It should be noted that in the following embodiments, the technical features of several different embodiments may be replaced, recombined, and mixed without departing from the spirit of the disclosure to complete other embodiments. As long as the features of each embodiment do not violate the spirit of the disclosure or conflict with each other, they may be mixed and used together arbitrarily.

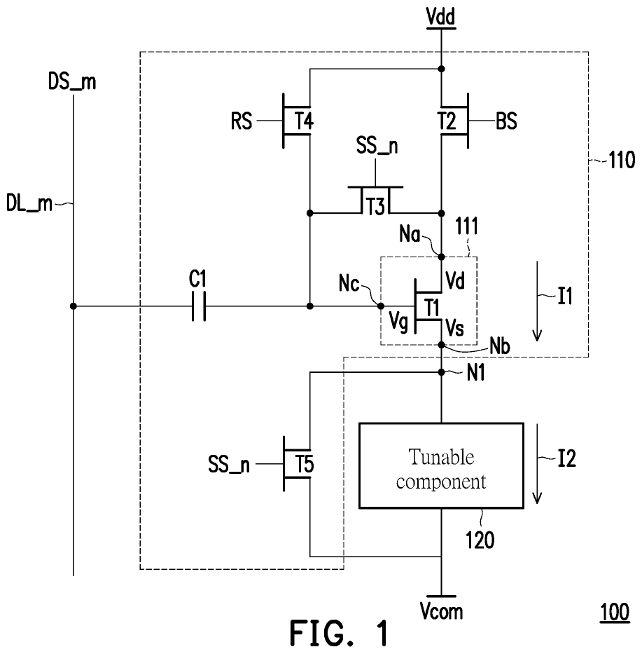

FIG. 1 is a schematic diagram of an electronic device according to an embodiment of the disclosure. Referring to FIG. 1, taking a (m,n)-th pixel as an example, the (m,n)-th pixel of the electronic device 100 includes a (source current type) constant voltage source circuit 110 and a tunable component 120. In the embodiment of the disclosure, m is between 1 and M, and n is between 1 and N. The constant voltage source circuit 110 is electrically connected to a circuit node N1. The constant voltage source circuit 110 includes a source follower circuit 111, a bias transistor T2, a compensation transistor T3, a reset transistor T4, a scan transistor T5 and a capacitor C1. The source follower circuit 111 includes a drive transistor T1. In the embodiment of the disclosure, the drive transistor T1 is configured to form a source follower amplifier. In the embodiment of the disclosure, the drive transistor T1 may be an n-type transistor (e.g. n-type

Metal-Oxide-Semiconductor (NMOS) transistor). The bias transistor T2, the compensation transistor T3, the reset transistor T4 and the scan transistor T5 may also be the n-type transistor, respectively, but the disclosure is not limited thereto.

In the embodiment of the disclosure, the source follower circuit 111 may include a first terminal Na, a second terminal Nb and a control terminal Nc. The control terminal Nc of the source follower circuit 111 is electrically connected to a control terminal (e.g. a gate terminal) of the drive transistor T1. The first terminal Na of the source follower circuit 111 is electrically connected to a first terminal (e.g. a drain terminal) of the drive transistor T1. The second terminal Nb of the source follower circuit 111 is electrically connected to a second terminal (e.g. a source terminal) of the drive transistor T1. In the embodiment of the disclosure, the control terminal Nc of the source follower circuit 111 is electrically connected to the first terminal Na of the source follower circuit 111. The control terminal Nc of the source follower circuit 111 is electrically connected to a data line DL_m (i.e. the m-th data line) through the capacitor C1.

In the embodiment of the disclosure, a first terminal of the capacitor C1 is electrically connected to the data line DL_m, and the data line DL_m is used to transmit a data signal DS_m with a data voltage or a reference voltage to the capacitor C1. A second terminal of the capacitor C1 is electrically connected to the control terminal Nc of the source follower circuit 111 (i.e. the control terminal of the drive transistor T1). The capacitor C1 is used to couple the data signal DS_m with the data voltage or the reference voltage to the control terminal Nc of the source follower circuit 111. The first terminal Na of the source follower circuit 111 (i.e. the first terminal of the drive transistor T1) is electrically connected to the bias transistor T2 and the compensation transistor T3. The first terminal Na of the source follower circuit 111 is electrically connected to the control terminal Nc of the source follower circuit 111 through the compensation transistor T3. The compensation transistor T3 is electrically connected between the control terminal Nc and the first terminal Na of the source follower circuit 111. The second terminal Nb of the source follower circuit 111 (i.e. the second terminal of the drive transistor T1) is electrically connected to the circuit node N1.

In the embodiment of the disclosure, a control terminal of the bias transistor T2 receives a bias signal BS, for example, through the n-th bias signal line. A first terminal of the bias transistor T2 is electrically connected to an operation voltage Vdd. A second terminal of the bias transistor T2 is electrically connected to the first terminal Na of the source follower circuit 111. In the embodiment of the disclosure, a control terminal of the compensation transistor T3 receives a scan signal SS_n, for example, through the n-th scan signal line. A first terminal of the compensation transistor T3 is electrically connected to the control terminal Nc of the source follower circuit 111. A second terminal of the compensation transistor T3 is electrically connected to the first terminal Na of the source follower circuit 111.

In the embodiment of the disclosure, a control terminal of the reset transistor T4 receives a reset signal RS, for example, through the n-th reset signal line. A first terminal of the reset transistor T4 is electrically connected to the operation voltage Vdd and the first terminal of the bias transistor T2. A second terminal of the reset transistor T4 is electrically connected to the control terminal Nc of the source follower circuit 111 and the first terminal of the compensation transistor T3. In the embodiment of the disclosure, the scan transistor T5 is electrically connected to the circuit node N1, and is electrically connected in parallel to the tunable component 120. A control terminal of the scan transistor T5 receives the scan signal SS_n, for example, through the n-th scan signal line. A first terminal of the scan transistor T5 is electrically connected to the second terminal Nb of the source follower circuit 111 and a first terminal of the tunable component 120. A second terminal of the scan transistor T5 is electrically connected to an operation voltage Vcom and a second terminal of the tunable component 120.

In the embodiment of the disclosure, the constant voltage source circuit 110 may effectively and automatically compensate a leakage current I2 of the tunable component 120 by a compensation current I1 (source current) generated by the source follower circuit 111, and at the same time, a threshold voltage Vth of the drive transistor T1 may also be compensated, so that a bias voltage of the tunable component 120 may be effectively maintained.

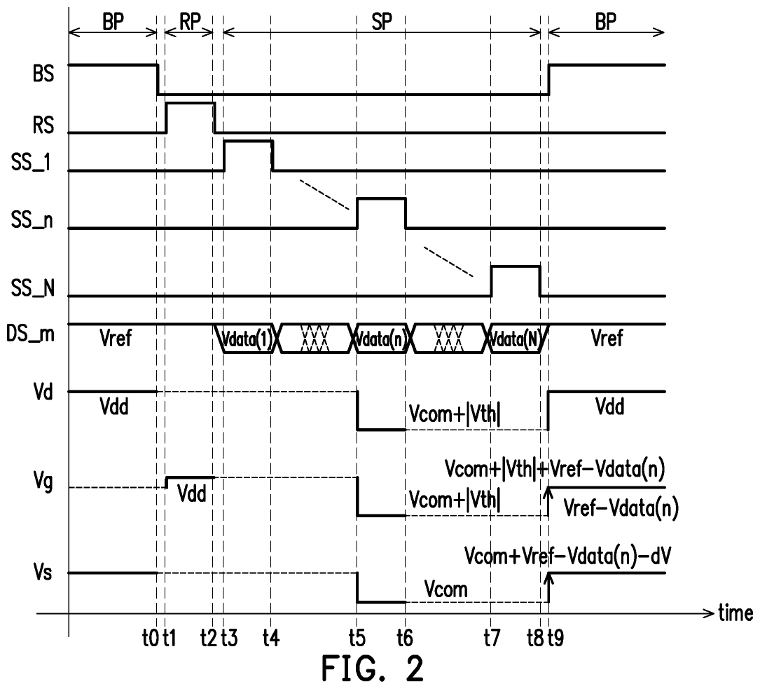

FIG. 2 is a timing diagram of related voltages and signals according to the embodiment of FIG. 1 of the disclosure. Referring to FIG. 1 and FIG. 2, in the embodiment of the disclosure, the M columns of the pixels of the electronic device 100 may respectively and sequentially receive different data signals through the M data signal lines. The N rows of the pixels of the electronic device 100 may respectively and sequentially receive different scan signals SS_1 to SS_N through the N scan signal lines. Thus, for example, the (m,n)-th pixel may receive a corresponding data signal through the m-th data line DL_m in a period specified by the scan signal SS_n through the n-th scan signal line. Each pixel of the electronic device 100 may receive the same bias signal BS through the N bias signal lines. Each pixel of the electronic device 100 may receive the same reset signal RS through the N reset signal lines.

During a reset period RP from time t1 to time t2, the reset signal RS is changed from a low voltage level to a high voltage, so that the reset transistor T4 is turned-on. The bias signal BS and the scan signals SS_1 to SS_N are maintained at the low voltage level, so that the bias transistor T2, the compensation transistor T3 and the scan transistor T5 are turned-off. Thus, a voltage Vg of the control terminal (i.e. the gate terminal) of the drive transistor T1 is reset to the operation voltage Vdd.

During a scan period SP from time t3 to time t8, the scan signals SS_1 to SS_N are sequentially changed from the low voltage level to the high voltage, and the data voltages Vdata(1) to Vdata(N) are sequentially stored into the corresponding capacitors of the pixels. For example, the scan signal SS_1 is changed from the low voltage level to the high voltage during the period from time t3 to time t4, and the data voltage Vdata(1) of m-th data signal DS_m is stored into the capacitor C1 of the (m,1)-th pixel through the m-th data signal line DL_m. The scan signal SS_n is changed from the low voltage level to the high voltage during the period from time t5 to time t6, so that the compensation transistor T3 and the scan transistor T5 are turned-on, and the data voltage Vdata(n) of m-th data signal DS_m is stored into the capacitor C1 of the (m,n)-th pixel through m-th data signal line DL_m. The scan signal SS_N is changed from the low voltage level to the high voltage during the period from time t7 to time t8, and the data voltage Vdata(N) of m-th data signal DS_m is stored into the capacitor C1 of the (m,N)-th pixel through m-th data signal line DL_m. Thus, during the period from time t5 to time t6, the data voltage Vdata(n) is stored into the capacitor C1. Moreover, due to the compensation transistor T3 and the scan transistor T5 are turned-on, a voltage Vs of the second terminal (i.e. the source terminal) of the drive transistor T1 is changed to the operation voltage Vcom, the voltage Vg of the control terminal of the drive transistor T1 is changed to the voltage of the operation voltage Vcom plus the threshold voltage |Vth| (i.e. Vcom+|Vth|), and a voltage Vd of the first terminal (i.e. the drain terminal) of the drive transistor T1 is also changed to the voltage of the operation voltage Vcom plus the threshold voltage |Vth|.

During a bias period BP after time t9 (and before time t0), the bias signal BS is changed from the low voltage level to the high voltage level, so that the bias transistor T2 is turned-on. The reset signal RS and the scan signals SS_1 to SS_N are maintained at the low voltage level, so that the compensation transistor T3, the reset transistor T4 and the scan transistor T5 are turned-off. Moreover, the data line DL_m may provide the data signal DS_m with the reference voltage Vref to the capacitor C1. Thus, the voltage of the reference voltage Vref minus the data voltage Vdata(n) (i.e. Vref−Vdata(n)) may be transferred to the control terminal of the drive transistor T1 with a capacitive coupling by the capacitor C1, so that the voltage Vg of the control terminal of the drive transistor T1 is changed to the voltage of the operation voltage Vcom plus the threshold voltage |Vth|, plus the reference voltage Vref, and minus the data voltage Vdata(n) (i.e. Vcom+|Vth|+Vref−Vdata(n)). The voltage Vd of the first terminal of the drive transistor T1 is changed to the operation voltage Vdd. The drive transistor T1 is operated as the source follower amplifier, so that the voltage Vs of the second terminal of the drive transistor T1 is changed to the voltage of the operation voltage Vcom plus the reference voltage Vref, minus the data voltage Vdata(n), and minus a voltage dV (i.e. Vcom+Vref−Vdata(n)−dV). The voltage dV is caused by the leakage current I2 to generate the compensation current I1. That is, the bias voltage (Vbias) for the tunable component 120 may be defined as the voltage of the reference voltage Vref minus the data voltage Vdata(n), and minus the voltage dV (i.e. Vref−Vdata(n)−dV).

Therefore, the tunable component 120 may be stably operated in a working state during the bias period BP. When the tunable component 120 occurs the leakage current I2, the bias voltage of the tunable component 120 may drop (Vbias−dV), and the voltage Vs of the second terminal of the drive transistor T1 may also drop. The drive transistor T1 may provide more current (i.e. the compensation current II) to the tunable component 120 to compensate the leakage current I2 of the tunable component 120, and at the same time, the threshold voltage 1Vthl of the drive transistor T1 can be compensated, so that the bias voltage (Vbias) of the tunable component 120 may be effectively maintained during the bias period BP.

In addition, in the embodiment of the disclosure, the operation voltage Vdd is equal to or higher than the voltage of the operation voltage Vcom plus the reference voltage Vref, and minus the data voltage Vdata(n) (i.e. Vcom+Vref−Vdata(n)), and the voltage of the operation voltage Vcom plus the reference voltage Vref, and minus the data voltage Vdata(n) (i.e. Vcom+Vref−Vdata(n)) is equal to or higher than the operation voltage Vcom.

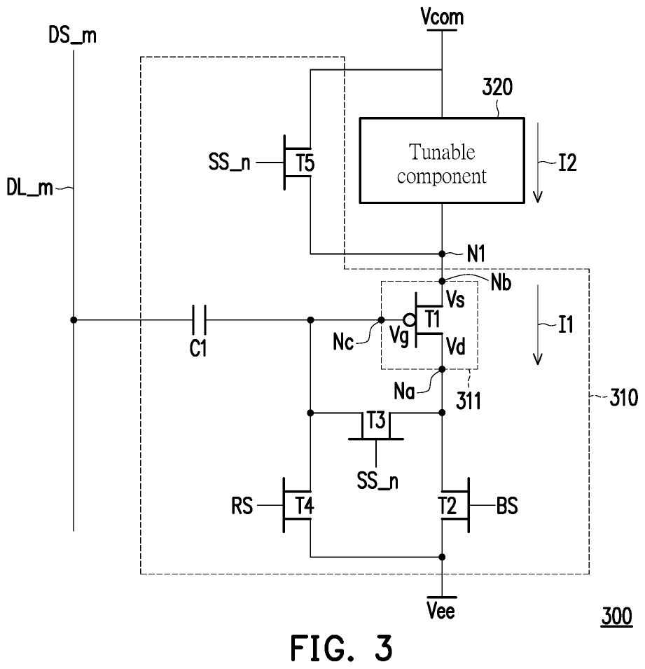

FIG. 3 is a schematic diagram of an electronic device according to an embodiment of he disclosure. Referring to FIG. 3, taking the (m,n)-th pixel as an example, the (m,n)-th pixel of the electronic device 300 includes a (sink current type) constant voltage source circuit 310 and a tunable component 320. The constant voltage source circuit 310 is electrically connected to a circuit node N1. The constant voltage source circuit 310 includes a source follower circuit 311, a bias transistor T2, a compensation transistor T3, a reset transistor T4, a scan transistor T5 and a capacitor C1. The source follower circuit 311 includes a drive transistor T1. In the embodiment of the disclosure, the drive transistor T1 is configured to form a source follower amplifier. In the embodiment of the disclosure, the drive transistor T1 may be a p-type transistor. The bias transistor T2, the compensation transistor T3, the reset transistor T4 and the scan transistor T5 may be the n-type transistor respectively, but the disclosure is not limited thereto.

In the embodiment of the disclosure, the source follower circuit 311 may include a first terminal Na, a second terminal Nb and a control terminal Nc. The control terminal Nc of the source follower circuit 311 is electrically connected to a control terminal (e.g. a gate terminal) of the drive transistor T1. The first terminal Na of the source follower circuit 311 is electrically connected to a first terminal (e.g. a drain terminal) of the drive transistor T1. The second terminal Nb of the source follower circuit 311 is electrically connected to a second terminal (e.g. a source terminal) of the drive transistor T1. In the embodiment of the disclosure, the control terminal Nc of the source follower circuit 311 is electrically connected to the first terminal Na of the source follower circuit 311. The control terminal Nc of the source follower circuit 311 is electrically connected to a data line DL_m (i.e. the m-th data line) through the capacitor C1.

In the embodiment of the disclosure, a first terminal of the capacitor C1 is electrically connected to the data line DL_m, and the data line DL_m is used to transmit a data signal DS_m with a data voltage or a reference voltage to the capacitor C1. A second terminal of the capacitor C1 is electrically connected to the control terminal Nc of the source follower circuit 311 (i.e. the control terminal of the drive transistor T1). The capacitor C1 is used to couple the data signal DS_m with the data voltage or the reference voltage to the control terminal Nc of the source follower circuit 311. The first terminal Na of the source follower circuit 311 (i.e. the first terminal of the drive transistor T1) is electrically connected to the bias transistor T2 and the compensation transistor T3. The first terminal Na of the source follower circuit 311 is electrically connected to the control terminal Nc of the source follower circuit 311 through the compensation transistor T3. The compensation transistor T3 is electrically connected between the control terminal Nc and the first terminal Na of the source follower circuit 311. The second terminal Nb of the source follower circuit 311 (i.e. the second terminal of the drive transistor T1) is electrically connected to the circuit node N1.

In the embodiment of the disclosure, a control terminal of the bias transistor T2 receives a bias signal BS, for example, through the n-th bias signal line. A first terminal of the bias transistor T2 is electrically connected to the first terminal Na of the source follower circuit 311. A second terminal of the bias transistor T2 is electrically connected to an operation voltage Vee. In the embodiment of the disclosure, a control terminal of the compensation transistor T3 receives a scan signal SS_n, for example, through the n-th scan signal line. A first terminal of the compensation transistor T3 is electrically connected to the first terminal Na of the source follower circuit 311. A second terminal of the compensation transistor T3 is electrically connected to the control terminal Nc of the source follower circuit 311.

In the embodiment of the disclosure, a control terminal of the reset transistor T4 receives a reset signal RS, for example, through the n-th reset signal line. A first terminal of the reset transistor T4 is electrically connected to the control terminal Nc of the source follower circuit 311 and the second terminal of the compensation transistor T3. A second terminal of the reset transistor T4 is electrically connected to the operation voltage Vee and the second terminal of the bias transistor T2. In the embodiment of the disclosure, the scan transistor T5 is electrically connected to the circuit node N1, and is electrically connected in parallel to the tunable component 320. A control terminal of the scan transistor T5 receives the scan signal SS_n, for example, through the n-th scan signal line. A first terminal of the scan transistor T5 is electrically connected to an operation voltage Vcom and a first terminal of the tunable component 320. A second terminal of the scan transistor T5 is electrically connected to the second terminal Nb of the source follower circuit 311 and a second terminal of the tunable component 320.

In the embodiment of the disclosure, the constant voltage source circuit 310 may effectively and automatically compensate a leakage current I2 of the tunable component 320 by a compensation current I1 (sink current) generated by the source follower circuit 311, and at the same time, a threshold voltage Vth of the drive transistor T1 may also be compensated, so that a bias voltage of the tunable component 320 may be effectively maintained.

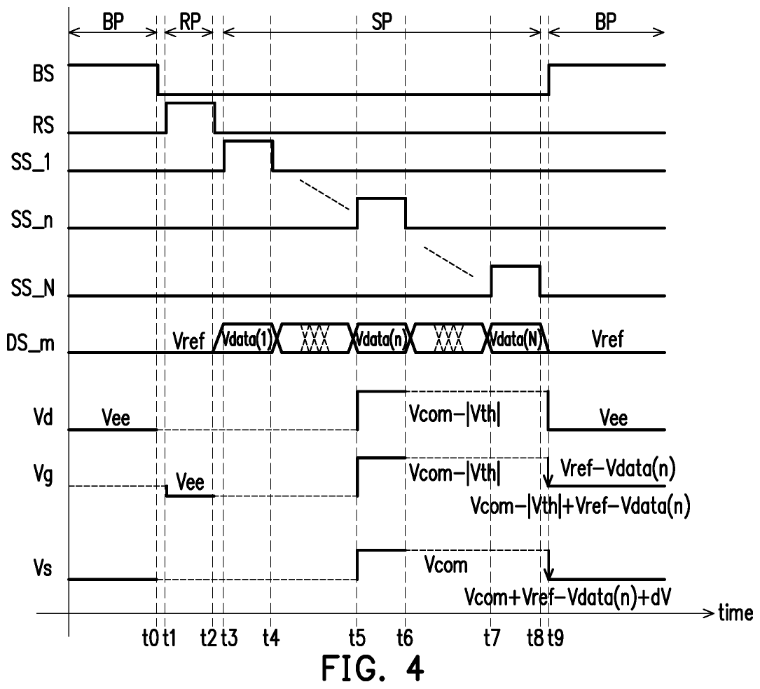

FIG. 4 is a timing diagram of related voltages and signals according to the embodiment of FIG. 3 of the disclosure. Referring to FIG. 3 and FIG. 4, in the embodiment of the disclosure, the M columns of the pixels of the electronic device 300 may respectively and sequentially receive different data signals through the M data signal lines. The N rows of the pixels of the electronic device 300 may respectively and sequentially receive different scan signals SS_1 to SS_N through the N scan signal lines. Thus, for example, the (m,n)-th pixel may receive a corresponding data signal through the m-th data line DL_m in a period specified by the scan signal SS_n through the n-th scan signal line. Each pixel of the electronic device 300 may receive the same bias signal BS through the N bias signal lines. Each pixel of the electronic device 300 may receive the same reset signal RS through the N reset signal lines.

During a reset period RP from time t1 to time t2, the reset signal RS is changed from a low voltage level to a high voltage, so that the reset transistor T4 is turned-on. The bias signal BS and the scan signals SS_1 to SS_N are maintained at the low voltage level, so that the bias transistor T2, the compensation transistor T3 and the scan transistor T5 are turned-off. Thus, a voltage Vg of the control terminal (i.e. the gate terminal) of the drive transistor T1 is reset to the operation voltage Vee.

During a scan period SP from time t3 to time t8, the scan signals SS_1 to SS_N are sequentially changed from the low voltage level to the high voltage, and the data voltages Vdata(1) to Vdata(N) are sequentially stored into the corresponding capacitors of the pixels. For example, the scan signal SS_1 is changed from the low voltage level to the high voltage during the period from time t3 to time t4, and the data voltage Vdata(1) of m-th data signal DS_m is stored into the capacitor C1 of the (m,1)-th pixel through m-th data signal line DL_m. The scan signal SS_n is changed from the low voltage level to the high voltage during the period from time t5 to time t6, so that the compensation transistor T3 and the scan transistor T5 are turned-on, and the data voltage Vdata(n) of m-th data signal DS_m is stored into the capacitor C1 of the (m,n)-th pixel through m-th data signal line DL_m. The scan signal SS_N is changed from the low voltage level to the high voltage during the period from time t7 to time t8, and the data voltage Vdata(N) of m-th data signal DS_m is stored into the capacitor C1 of the (m,N)-th pixel through m-th data signal line DL_m. Thus, during the period from time t5 to time t6, the data voltage Vdata(n) is stored into the capacitor C1. Moreover, due to the compensation transistor T3 and the scan transistor T5 are turned-on, a voltage Vs of the second terminal (i.e. the source terminal) of the drive transistor T1 is changed to the operation voltage Vcom, the voltage Vg of the control terminal of the drive transistor T1 is changed to the voltage of the operation voltage Vcom minus the threshold voltage |Vth| (i.e. Vcom−|Vth|), and a voltage Vd of the first terminal (i.e. the drain terminal) of the drive transistor T1 is also changed to the voltage of the operation voltage Vcom minus the threshold voltage |Vth|.

During a bias period BP after time t9 (and before time tO), the bias signal BS is changed from the low voltage level to the high voltage level, so that the bias transistor T2 is turned-on. The reset signal RS and the scan signals SS_1 to SS_N are maintained at the low voltage level, so that the compensation transistor T3, the reset transistor T4 and the scan transistor T5 are turned-off. Moreover, the data line DL_m may provide the data signal DS_m with the reference voltage Vref to the capacitor C1. Thus, the voltage of the reference voltage Vref minus the data voltage Vdata(n) (i.e. Vref−Vdata(n)) may be transferred to the control terminal of the drive transistor T1 with a capacitive coupling by the capacitor C1, so that the voltage Vg of the control terminal of the drive transistor T1 is changed to the voltage of the operation voltage Vcom minus the threshold voltage |Vth|, plus the reference voltage Vref, and minus the data voltage Vdata(n) (i.e. Vcom−|Vth|+Vref−Vdata(n)). The voltage Vd of the first terminal of the drive transistor T1 is changed to the operation voltage Vee. The drive transistor T1 is operated as the source follower amplifier, so that the voltage Vs of the second terminal of the drive transistor T1 is changed to the voltage of the operation voltage Vcom plus the reference voltage Vref, minus the data voltage Vdata(n), and plus a voltage dV (i.e. Vcom+Vref−Vdata(n)+dV). The voltage dV is caused by the leakage current 12 to generate the compensation current I1. That is, the bias voltage (Vbias) for the tunable component 320 may be defined as the voltage of the reference voltage Vref minus the data voltage Vdata(n), and plus the voltage dV (i.e. Vref−Vdata(n)+dV).

Therefore, the tunable component 320 may be stably operated in a working state during the bias period BP. When the tunable component 320 occurs the leakage current I2, the bias voltage of the tunable component 320 may rise (Vbias+dV), and the voltage Vs of the second terminal of the drive transistor T1 may also rise. The drive transistor T1 may discharge more current (i.e. the compensation current I1) from the tunable component 320 to compensate the leakage current I2 of the tunable component 320, and at the same time, the threshold voltage |Vth| of the drive transistor T1 can be compensated, so that the bias voltage (Vbias) of the tunable component 320 may be effectively maintained during the bias period BP.

In addition, in the embodiment of the disclosure, the operation voltage Vcom is equal to or higher than the voltage of the operation voltage Vcom plus the reference voltage Vref, and minus the data voltage Vdata(n) (i.e. Vcom+Vref−Vdata(n)), and the voltage of the operation voltage Vcom plus the reference voltage Vref, and minus the data voltage Vdata(n) (i.e. Vcom+Vref−Vdata(n)) is equal to or higher than the operation voltage Vee.

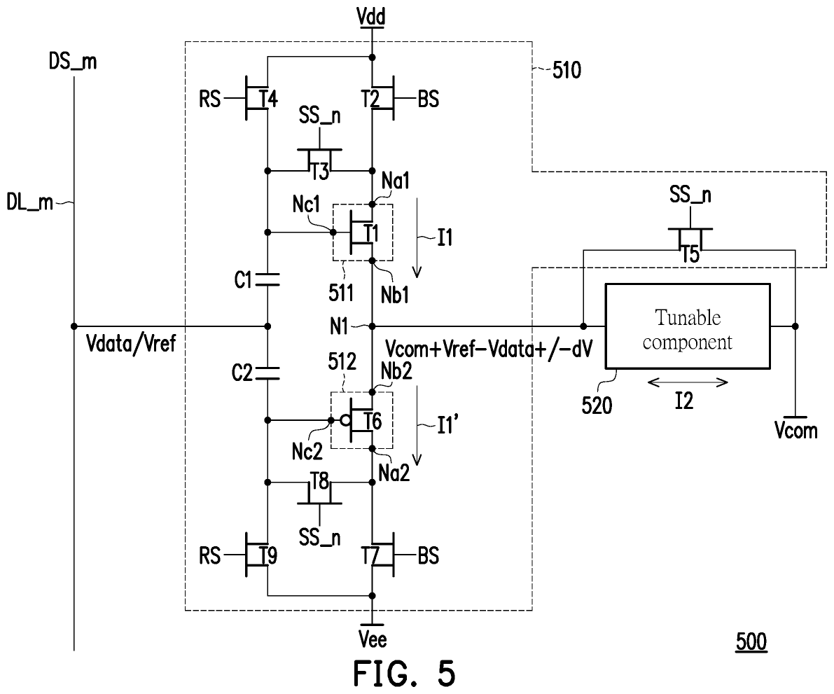

FIG. 5 is a schematic diagram of an electronic device according to an embodiment of the disclosure. Referring to FIG. 5, taking the (m,n)-th pixel as an example, the (m,n)-th pixel of the electronic device 500 includes a constant voltage source circuit 510 and a tunable component 520. The constant voltage source circuit 510 is electrically connected to a circuit node N1. The constant voltage source circuit 510 includes source follower circuits 511, 512, bias transistors T2, T7, compensation transistors T3, T8, reset transistors T4, T9, a scan transistor T5 and capacitors C1, C2. The source follower circuit 511 includes a drive transistor T1. In the embodiment of the disclosure, the drive transistor T1 is configured to form a first source follower amplifier. In the embodiment of the disclosure, the drive transistor T1 may be the n-type transistor. The source follower circuit 512 includes a drive transistor T6. In the embodiment of the disclosure, the drive transistor T6 is configured to form a second source follower amplifier. In the embodiment of the disclosure, the drive transistor T6 may be a p-type transistor. The bias transistors T2, T7, the compensation transistors T3, T8, the reset transistors T4, T9 and the scan transistor T5 may also be the n-type transistor, respectively, but the disclosure is not limited thereto.

In the embodiment of the disclosure, the source follower circuit 511 may include a first terminal Na1, a second terminal Nb1 and a control terminal Nc1. The control terminal Nc1 of the source follower circuit 511 is electrically connected to a control terminal (e.g. a gate terminal) of the drive transistor T1. The first terminal Na1 of the source follower circuit 511 is electrically connected to a first terminal (e.g. a drain terminal) of the drive transistor T1. The second terminal Nb1 of the source follower circuit 511 is electrically connected to a second terminal (e.g. a source terminal) of the drive transistor T1. In the embodiment of the disclosure, the control terminal Nc1 of the source follower circuit 511 is electrically connected to the first terminal Na1 of the source follower circuit 511. The control terminal Nc1 of the source follower circuit 511 is electrically connected to a data line DL_m (i.e. the m-th data line) through the capacitor C1.

In the embodiment of the disclosure, the source follower circuit 512 may include a first terminal Na2, a second terminal Nb2 and a control terminal Nc2. The control terminal Nc2 of the source follower circuit 512 is electrically connected to a control terminal (e.g. a gate terminal) of the drive transistor T6. The first terminal Na2 of the source follower circuit 512 is electrically connected to a first terminal (e.g. a drain terminal) of the drive transistor T6. The second terminal Nb2 of the source follower circuit 512 is electrically connected to a second terminal (e.g. a source terminal) of the drive transistor T6. In the embodiment of the disclosure, the control terminal Nc2 of the source follower circuit 512 is electrically connected to the first terminal Na2 of the source follower circuit 512. The control terminal Nc2 of the source follower circuit 512 is electrically connected to the data line DL_m (i.e. the m-th data line) through the capacitor C2.

In the embodiment of the disclosure, a first terminal of the capacitor C1 is electrically connected to the data line DL_m, and the data line DL_m is used to transmit a data signal DS_m with a data voltage Vdata or a reference voltage Vref to the capacitor C1. A second terminal of the capacitor C1 is electrically connected to the control terminal Nc1 of the source follower circuit 511 (i.e. the control terminal of the drive transistor T1). The capacitor C1 is used to couple the data signal DS_m with the data voltage or the reference voltage to the control terminal Nc1 of the source follower circuit 511. The first terminal Na1 of the source follower circuit 511 (i.e. the first terminal of the drive transistor T1) is electrically connected to the bias transistor T2 and the compensation transistor T3. The first terminal Na1 of the source follower circuit 511 is electrically connected to the control terminal Nc1 of the source follower circuit 511 through the compensation transistor T3. The compensation transistor T3 is electrically connected between the control terminal Nc1 and the first terminal Na1 of the source follower circuit 511. The second terminal Nb1 of the source follower circuit 511 (i.e. the second terminal of the drive transistor T1) is electrically connected to the circuit node N1.

In the embodiment of the disclosure, a control terminal of the bias transistor T2 receives a bias signal BS, for example, through the n-th bias signal line. A first terminal of the bias transistor T2 is electrically connected to an operation voltage Vdd. A second terminal of the bias transistor T2 is electrically connected to the first terminal Na1 of the source follower circuit 511.

In the embodiment of the disclosure, a control terminal of the compensation transistor T3 receives a scan signal SS_n, for example, through the n-th scan signal line. A first terminal of the compensation transistor T3 is electrically connected to the control terminal Nc1 of the source follower circuit 511. A second terminal of the compensation transistor T3 is electrically connected to the first terminal Na1 of the source follower circuit 511.

In the embodiment of the disclosure, a control terminal of the reset transistor T4 receives a reset signal RS, for example, through the n-th reset signal line. A first terminal of the reset transistor T4 is electrically connected to the operation voltage Vdd and the first terminal of the bias transistor T2. A second terminal of the reset transistor T4 is electrically connected to the control terminal Nc1 of the source follower circuit 511 and the first terminal of the compensation transistor T3. In the embodiment of the disclosure, the scan transistor T5 is electrically connected to the circuit node N1, and is electrically connected in parallel to the tunable component 520. A control terminal of the scan transistor T5 receives the scan signal SS_n, for example, through the n-th scan signal line. A first terminal of the scan transistor T5 is electrically connected to the second terminal Nb1 of the source follower circuit 511 and a first terminal of the tunable component 520. A second terminal of the scan transistor T5 is electrically connected to an operation voltage Vcom and a second terminal of the tunable component 520.

In the embodiment of the disclosure, a first terminal of the capacitor C2 is electrically connected to the data line DL_m, and the data line DL_m is used to transmit a data signal DS_m with a data voltage Vdata or a reference voltage Vref to the capacitor C2. A second terminal of the capacitor C2 is electrically connected to the control terminal Nc2 of the source follower circuit 512 (i.e. the control terminal of the drive transistor T1). The capacitor C2 is used to couple the data signal DS_m with the data voltage Vdata or the reference voltage Vref to the control terminal Nc2 of the source follower circuit 512. The first terminal Na2 of the source follower circuit 512 (i.e. the first terminal of the drive transistor T6) is electrically connected to the bias transistor T7 and the compensation transistor T8. The first terminal Na2 of the source follower circuit 512 is electrically connected to the control terminal Nc2 of the source follower circuit 512 through the compensation transistor T8. The compensation transistor T8 is electrically connected between the control terminal Nc2 and the first terminal Na2 of the source follower circuit 512. The second terminal Nb2 of the source follower circuit 512 (i.e. the second terminal of the drive transistor T6) is electrically connected to the circuit node N1.

In the embodiment of the disclosure, a control terminal of the bias transistor T7 receives the bias signal BS, for example, through the n-th bias signal line. A first terminal of the bias transistor T7 is electrically connected to the first terminal Na2 of the source follower circuit 512. A second terminal of the bias transistor T7 is electrically connected to an operation voltage Vee. In the embodiment of the disclosure, a control terminal of the compensation transistor T8 receives the scan signal SS_n, for example, through the n-th scan signal line. A first terminal of the compensation transistor T8 is electrically connected to the first terminal Na2 of the source follower circuit 512. A second terminal of the compensation transistor T8 is electrically connected to the control terminal Nc2 of the source follower circuit 512.

In the embodiment of the disclosure, a control terminal of the reset transistor T9 receives the reset signal RS, for example, through the n-th reset signal line. A first terminal of the reset transistor T9 is electrically connected to the control terminal Nc2 of the source follower circuit 512 and the second terminal of the compensation transistor T8. A second terminal of the reset transistor T9 is electrically connected to the operation voltage Vee and the second terminal of the bias transistor T7.

In the embodiment of the disclosure, the constant voltage source circuit 510 may effectively and automatically compensate a leakage current I2 of the tunable component 520 by a compensation current I1 (source current) generated by the source follower circuit 511 or a compensation current I1′ (sink current) generated by the source follower circuit 512, and at the same time, a threshold voltage of the drive transistor T1 and another threshold voltage of the drive transistor T6 may also be compensated, so that a bias voltage (Vbias) of the tunable component 520 may be effectively maintained.

In the embodiment of the disclosure, the constant voltage source circuit 510 may provide the voltage of the operation voltage Vcom plus the reference voltage Vref, minus the data voltage Vdata, and plus/minus a voltage dV (i.e. Vcom+Vref−Vdata+/−dV). The voltage dV is caused by the leakage current I2 to generate the compensation current I1 or the compensation current I1′. That is, the bias voltage for the tunable component 520 may be defined as the voltage of the reference voltage Vref minus the data voltage Vdata, and plus/minus the voltage dV (i.e. Vref−Vdata+/−dV).

In addition, in the embodiment of the disclosure, the operation voltage Vdd is equal to or higher than the voltage of the operation voltage Vcom plus the reference voltage Vref, and minus the data voltage Vdata (i.e. Vcom+Vref−Vdata), and the voltage of the operation voltage Vcom plus the reference voltage Vref, and minus the data voltage Vdata (i.e. Vcom+Vref−Vdata) is equal to or higher than the operation voltage Vee. The operation voltage Vdd is higher than the operation voltage Vcom, and the operation voltage Vcom is higher than the operation voltage Vee.

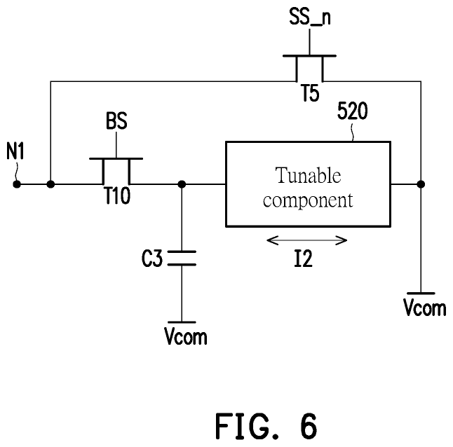

FIG. 6 is a partial circuit schematic diagram of the electronic device according to another embodiment of FIG. 5 of the disclosure. In one embodiment of the disclosure, the constant voltage source circuit 510 of FIG. 5 may further includes a bias transistor T10 and a capacitor C3, and the bias transistor T10 may be the n-type transistor, but the disclosure is not limited thereto. As shown in FIG. 6, a control terminal of the bias transistor T10 receives the bias signal BS. A first terminal of the bias transistor T10 is electrically connected to the circuit node N1 and the first terminal of the scan transistor T5. A second terminal of the bias transistor T10 is electrically connected to the first terminal of the tunable component 520. A first terminal of the capacitor C3 is electrically connected to the second terminal of the bias transistor T10 and the first terminal of the tunable component 520. A second terminal of the capacitor C3 is electrically connected to the operation voltage Vcom.

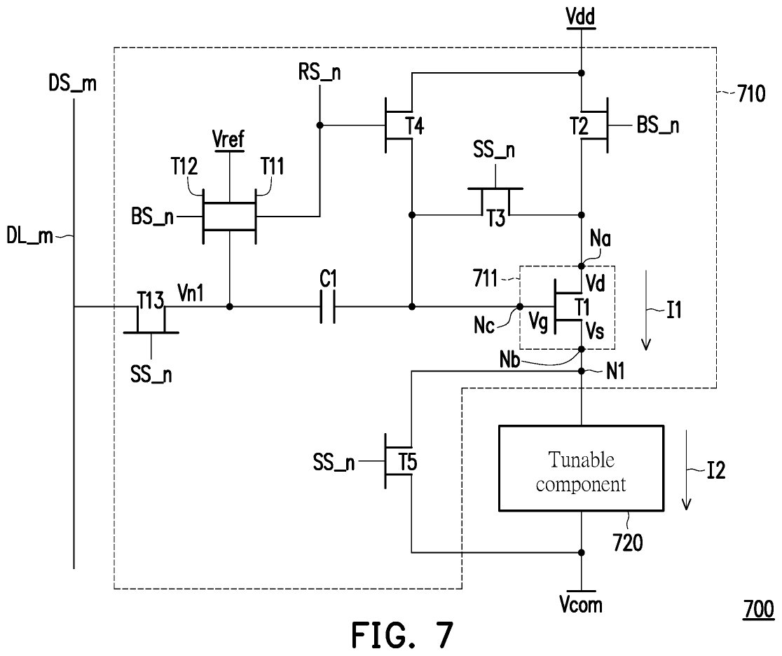

In the embodiment of the disclosure, during the bias period, the bias transistor T10 may be turned-on by the bias signal BS to provide the bias voltage to the tunable component 520, and the bias voltage may also be store into the capacitor C3. Thus, during the reset period and the scan period, the bias transistor T10 may be turned-off by the bias signal BS, and the capacitor C3 may continuously provide the pre-stored bias voltage to the tunable component 520. Therefore, the tunable component 520 may still be stably driven by the bias voltage during the reset period and the scan period. FIG. 7 is a schematic diagram of an electronic device according to an embodiment of the

disclosure. Referring to FIG. 7, taking the (m,n)-th pixel as an example, the (m,n)-th pixel of the electronic device 700 includes a (source current type) constant voltage source circuit 710 and a tunable component 720. The constant voltage source circuit 710 is electrically connected to a circuit node N1. The constant voltage source circuit 710 includes a source follower circuit 711, bias transistors T2, T12, a compensation transistor T3, reset transistors T4, T11, scan transistors T5, T13 and a capacitor C1. The source follower circuit 711 includes a drive transistor T1. In the embodiment of the disclosure, the drive transistor T1 is configured to form a source follower amplifier. In the embodiment of the disclosure, the drive transistor T1 may be an n-type transistor. The bias transistors T2, T12, the compensation transistor T3, the reset transistors T4, T11 and the scan transistors T5, T13 may also be the n-type transistor, respectively, but the disclosure is not limited thereto.

In the embodiment of the disclosure, the source follower circuit 711 may include a first terminal Na, a second terminal Nb and a control terminal Nc. The control terminal Nc of the source follower circuit 711 is electrically connected to a control terminal (e.g. a gate terminal) of the drive transistor T1. The first terminal Na of the source follower circuit 711 is electrically connected to a first terminal (e.g. a drain terminal) of the drive transistor T1. The second terminal Nb of the source follower circuit 711 is electrically connected to a second terminal (e.g. a source terminal) of the drive transistor T1. In the embodiment of the disclosure, the control terminal Nc of the source follower circuit 711 is electrically connected to the first terminal Na of the source follower circuit 711. The control terminal Nc of the source follower circuit 711 is electrically connected to a data line DL_m (i.e. the m-th data line) through the capacitor C1 and the scan transistor T13. In the embodiment of the disclosure, the reset transistor T11, the bias transistor T12 and the scan transistor T13 are electrically connected to the capacitor C1.

In the embodiment of the disclosure, a control terminal of the scan transistor T13 receives a scan signal SS_n, for example, through the n-th scan signal line. A first terminal of the scan transistor T13 is electrically connected to the data line DL_m. A second terminal of the scan transistor T13 is electrically connected to a first terminal of the capacitor C1. The data line DL_m is used to transmit a data signal DS_m with a data voltage to the capacitor C1 through the scan transistor T13. A second terminal of the capacitor C1 is electrically connected to the control terminal Nc of the source follower circuit 711 (i.e. the control terminal of the drive transistor T1).

The capacitor C1 is used to couple the data signal DS_m with the data voltage or a reference voltage to the control terminal Nc of the source follower circuit 711. The first terminal Na of the source follower circuit 711 (i.e. the first terminal of the drive transistor T1) is electrically connected to the bias transistor T2 and the compensation transistor T3. The first terminal Na of the source follower circuit 711 is electrically connected to the control terminal Nc of the source follower circuit 711 through the compensation transistor T3. The compensation transistor T3 is electrically connected between the control terminal Nc and the first terminal Na of the source follower circuit 711. The second terminal Nb of the source follower circuit 711 (i.e. the second terminal of the drive transistor T1) is electrically connected to the circuit node N1.

In the embodiment of the disclosure, a control terminal of the bias transistor T2 receives a bias signal BS_n, for example, through the n-th bias signal line. A first terminal of the bias transistor T2 is electrically connected to an operation voltage Vdd. A second terminal of the bias transistor T2 is electrically connected to the first terminal Na of the source follower circuit 711. In the embodiment of the disclosure, a control terminal of the compensation transistor T3 receives the scan signal SS_n, for example, through the n-th scan signal line. A first terminal of the compensation transistor T3 is electrically connected to the control terminal Nc of the source follower circuit 711. A second terminal of the compensation transistor T3 is electrically connected to the first terminal Na of the source follower circuit 711.

In the embodiment of the disclosure, a control terminal of the reset transistor T4 receives a reset signal RS_n, for example, through the n-th reset signal line. A first terminal of the reset transistor T4 is electrically connected to the operation voltage Vdd and the first terminal of the bias transistor T2. A second terminal of the reset transistor T4 is electrically connected to the control terminal Nc of the source follower circuit 711 and the first terminal of the compensation transistor T3. In the embodiment of the disclosure, the scan transistor T5 is electrically connected to the circuit node N1, and is electrically connected in parallel to the tunable component 720. A control terminal of the scan transistor T5 receives the scan signal SS_n, for example, through the n-th scan signal line. A first terminal of the scan transistor T5 is electrically connected to the second terminal Nb of the source follower circuit 711 and a first terminal of the tunable component 720. A second terminal of the scan transistor T5 is electrically connected to an operation voltage Vcom and a second terminal of the tunable component 720.

In the embodiment of the disclosure, a control terminal of the reset transistor T11 receives the reset signal RS_n, for example, through the n-th reset signal line. A first terminal of the reset transistor T11 is electrically connected to a reference voltage Vref. A second terminal of the reset transistor T11 is electrically connected to the first terminal of the capacitor C1. In the embodiment of the disclosure, a control terminal of the bias transistor T12 receives the bias signal BS_n, for example, through the n-th bias signal line. A first terminal of the bias transistor T12 is electrically connected to the reference voltage Vref. A second terminal of the bias transistor T12 is electrically connected to the first terminal of the capacitor C1.

In the embodiment of the disclosure, the constant voltage source circuit 710 may effectively and automatically compensate a leakage current I2 of the tunable component 720 by a compensation current I1 (source current) generated by the source follower circuit 711, and at the same time, a threshold voltage Vth of the drive transistor T1 may also be compensated, so that a bias voltage of the tunable component 720 may be effectively maintained.

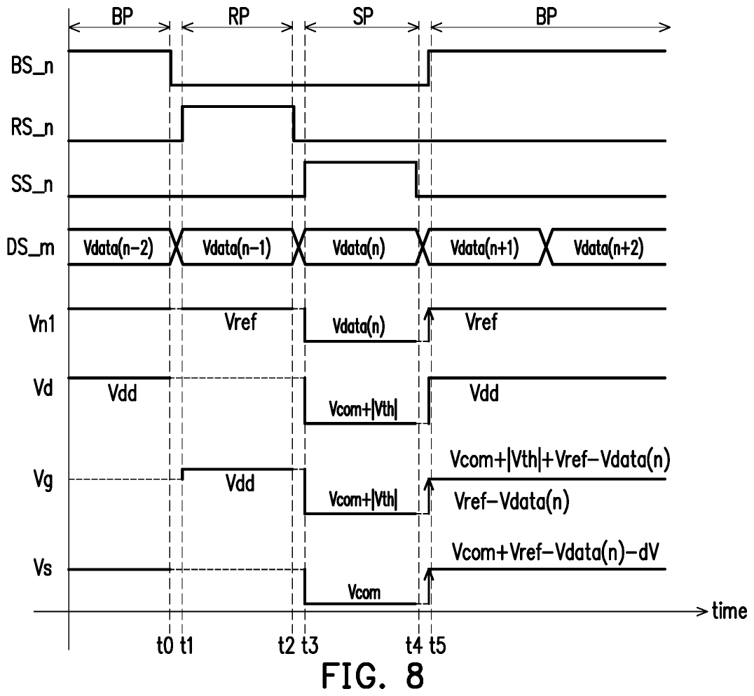

FIG. 8 is a timing diagram of related voltages and signals according to the embodiment of FIG. 7 of the disclosure. Referring to FIG. 7 and FIG. 8, in the embodiment of the disclosure, the M columns of the pixels of the electronic device 700 may respectively and sequentially receive different data signals through the M data signal lines. The N rows of the pixels of the electronic device 100 may respectively and sequentially receive different scan signals through the N scan signal lines. The N rows of the pixels of the electronic device 700 may respectively and sequentially receive the different bias signals through the N bias signal lines. The N rows of the pixels of the electronic device 700 may respectively and sequentially receive the different reset signals through the N reset signal lines. Thus, for example, the (m,n)-th pixel may receive a corresponding data signal through the m-th data signal line DL_m in a period specified by the scan signal SS_n through the n-th scan signal line, the bias signal BS_n though the n-th bias signal line and the reset signal RS_n through the n-th reset signal line.

During a reset period RP from time t1 to time t2, the reset signal RS_n is changed from a low voltage level to a high voltage, so that the reset transistors T4, T11 are turned-on. The bias signal BS_n and the scan signal SS_n are maintained at the low voltage level, so that the bias transistors T2, T12, the compensation transistor T3 and the scan transistors T5, T13 are turned-off. Thus, a voltage Vg of the control terminal (i.e. the gate terminal) of the drive transistor T1 is reset to the operation voltage Vdd, and a voltage Vn1 of the first terminal of the capacitor C1 is reset to the reference voltage Vref, respectively.

During a scan period SP from time t3 to time t4, the scan signal SS_n is changed from the low voltage level to the high voltage, and the data voltage Vdata(n) is stored into the capacitor C1. Moreover, due to the compensation transistor T3 and the scan transistors T5 are turned-on, a voltage Vs of the second terminal (i.e. the source terminal) of the drive transistor T1 is changed to the operation voltage Vcom, the voltage Vg of the control terminal of the drive transistor T1 is changed to the voltage of the operation voltage Vcom plus the threshold voltage |Vth| (i.e. Vcom+|Vth|), and a voltage Vd of the first terminal (i.e. the drain terminal) of the drive transistor T1 is also changed to the voltage of the operation voltage Vcom plus the threshold voltage |Vth|. Due to the scan transistors T13 is turned-on, the voltage Vnl of the first terminal of the capacitor C1 is changed to the data voltage Vdata(n). In addition, the data signal DS_m may respectively and sequentially provide different data voltages (e.g. data voltages Vdata(n−2) to Vdata(n+2)) to different rows of the pixels during different periods as shown in FIG. 8.

During a bias period BP after time t5 (and before time t0), the bias signal BS_n is changed from the low voltage level to the high voltage level, so that the bias transistors T2, T12 are turned-on. The reset signal RS_n and the scan signal SS_n are maintained at the low voltage level, so that the compensation transistor T3, the reset transistors T4, T11 and the scan transistors T5, T13 are turned-off. Moreover, the bias transistor T12 may provide the reference voltage Vref to the first terminal of the capacitor C1. Thus, the voltage of the reference voltage Vref minus the data voltage Vdata(n) (i.e. Vref−Vdata(n)) may be transferred to the control terminal of the drive transistor T1 with a capacitive coupling by the capacitor C1, so that the voltage Vg of the control terminal of the drive transistor T1 is changed to the voltage of the operation voltage Vcom plus the threshold voltage |Vth|, plus the reference voltage Vref, and minus the data voltage Vdata(n) (i.e. Vcom+|Vth|+Vref−Vdata(n)). The voltage Vd of the first terminal of the drive transistor T1 is changed to the operation voltage Vdd. The drive transistor T1 is operated as the source follower amplifier, so that the voltage Vs of the drive transistor T1 is changed to the voltage of the operation voltage Vcom plus the reference voltage Vref, minus the data voltage Vdata(n), and minus a voltage dV (i.e. Vcom+Vref−Vdata(n)-dV). The voltage dV is caused by the leakage current I2 to generate the compensation current I1. That is, the bias voltage (Vbias) for the tunable component 120 may be defined as the voltage of the reference voltage Vref minus the data voltage Vdata(n), and minus the voltage dV (i.e. Vref−Vdata(n)−dV).

Therefore, the tunable component 720 may be stably operated in a working state during the bias period BP. When the tunable component 720 occurs the leakage current I2, the bias voltage of the tunable component 720 may drop (Vbias−dV), and the voltage Vs of the second terminal of the drive transistor T1 may also drop. The drive transistor T1 may provide more current (i.e. the compensation current I1) to the tunable component 720 to compensate the leakage current I2 of the tunable component 720, and at the same time, the threshold voltage 1Vthl of the drive transistor T1 can be compensated, so that the bias voltage (Vbias) of the tunable component 720 may be effectively maintained during the bias period BP.

In addition, in the embodiment of the disclosure, the operation voltage Vdd is equal to or higher than the voltage of the operation voltage Vcom plus the reference voltage Vref, and minus the data voltage Vdata(n) (i.e. Vcom+Vref−Vdata(n)), and the voltage of the operation voltage Vcom plus the reference voltage Vref, and minus the data voltage Vdata(n) (i.e. Vcom+Vref−Vdata(n)) is equal to or higher than the operation voltage Vcom.

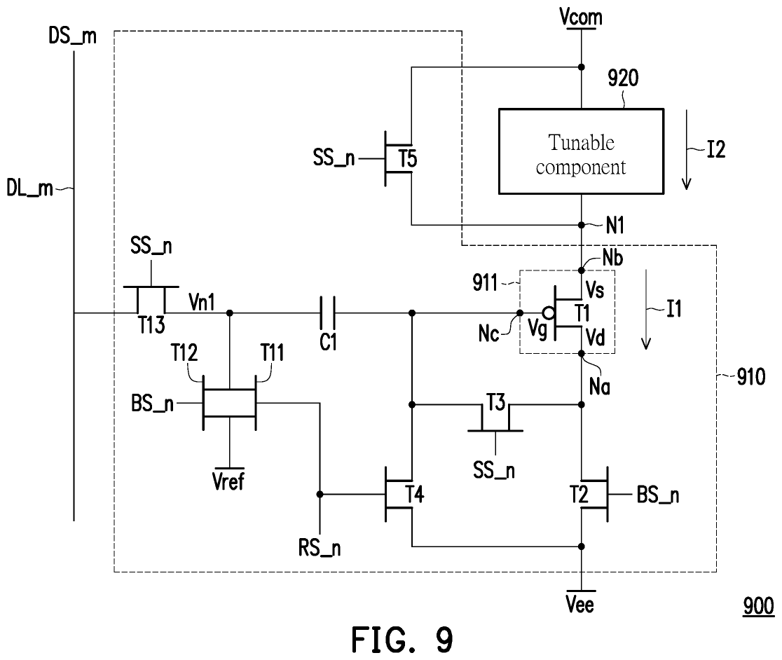

FIG. 9 is a schematic diagram of an electronic device according to an embodiment of the disclosure. Referring to FIG. 9, taking the (m,n)-th pixel as an example, the (m,n)-th pixel of the electronic device 900 includes a (sink current type) constant voltage source circuit 910 and a tunable component 920. The constant voltage source circuit 910 is electrically connected to a circuit node N1. The constant voltage source circuit 910 includes a source follower circuit 911, bias transistors T2, T12, a compensation transistor T3, reset transistors T4, T11, scan transistors T5, T13 and a capacitor C1. The source follower circuit 911 includes a drive transistor T1. In the embodiment of the disclosure, the drive transistor T1 is configured to form a source follower amplifier. In the embodiment of the disclosure, the drive transistor T1 may be a p-type transistor. The bias transistors T2, T12, the compensation transistor T3, the reset transistors T4, T11 and the scan transistors T5, T13 may be the n-type transistor respectively, but the disclosure is not limited thereto.

In the embodiment of the disclosure, the source follower circuit 911 may include a first terminal Na, a second terminal Nb and a control terminal Nc. The control terminal of the source follower circuit 911 is electrically connected to a control terminal (e.g. a gate terminal) of the drive transistor T1. The first terminal Na of the source follower circuit 911 is electrically connected to a first terminal (e.g. a drain terminal) of the drive transistor T1. The second terminal Nb of the source follower circuit 911 is electrically connected to a second terminal (e.g. a source terminal) of the drive transistor T1. In the embodiment of the disclosure, the control terminal Nc of the source follower circuit 911 is electrically connected to the first terminal Na of the source follower circuit 911. The control terminal Nc of the source follower circuit 911 is electrically connected to a data line DL_m (i.e. the m-th data line) through the capacitor C1 and the scan transistor T13. In the embodiment of the disclosure, the reset transistor T11, the bias transistor T12 and the scan transistor T13 are electrically connected to the capacitor C1.

In the embodiment of the disclosure, a control terminal of the scan transistor T13 receives a scan signal SS_n, for example, through the n-th scan signal line. A first terminal of the scan transistor T13 is electrically connected to the data line DL_m. A second terminal of the scan transistor T13 is electrically connected to a first terminal of the capacitor C1. The data line DL_m is used to transmit a data signal DS_m with a data voltage to the capacitor C1 through the scan transistor T13. A second terminal of the capacitor C1 is electrically connected to the control terminal Nc of the source follower circuit 911 (i.e. the control terminal of the drive transistor T1). The capacitor C1 is used to couple the data signal DS_m with the data voltage or a reference voltage to the control terminal Nc of the source follower circuit 911. The first terminal Na of the source follower circuit 911 (i.e. the first terminal of the drive transistor T1) is electrically connected to the bias transistor T2 and the compensation transistor T3. The first terminal Na of the source follower circuit 911 is electrically connected to the control terminal Nc of the source follower circuit 911 through the compensation transistor T3. The compensation transistor T3 is electrically connected between the control terminal Nc and the first terminal Na of the source follower circuit 911. The second terminal Nb of the source follower circuit 911 (i.e. the second terminal of the drive transistor T1) is electrically connected to the circuit node N1.

In the embodiment of the disclosure, a control terminal of the bias transistor T2 receives a bias signal BS_n, for example, through the n-th bias signal line. A first terminal of the bias transistor T2 is electrically connected to the first terminal Na of the source follower circuit 911. A second terminal of the bias transistor T2 is electrically connected to an operation voltage Vee. In the embodiment of the disclosure, a control terminal of the compensation transistor T3 receives a scan signal SS_n, for example, through the n-th scan signal line. A first terminal of the compensation transistor T3 is electrically connected to the first terminal Na of the source follower circuit 911. A second terminal of the compensation transistor T3 is electrically connected to the control terminal Nc of the source follower circuit 911.

In the embodiment of the disclosure, a control terminal of the reset transistor T4 receives a reset signal RS_n, for example, through the n-th reset signal line. A first terminal of the reset transistor T4 is electrically connected to the control terminal Nc of the source follower circuit 911 and the second terminal of the compensation transistor T3 . A second terminal of the reset transistor T4 is electrically connected to the operation voltage Vee and the second terminal of the bias transistor T2. In the embodiment of the disclosure, the scan transistor T5 is electrically connected to the circuit node N1, and is electrically connected in parallel to the tunable component 920. A control terminal of the scan transistor T5 receives the scan signal SS_n, for example, through the n-th scan signal line. A first terminal of the scan transistor T5 is electrically connected to an operation voltage Vcom and a first terminal of the tunable component 920. A second terminal of the scan transistor T5 is electrically connected to the second terminal Nb of the source follower circuit 911 and a second terminal of the tunable component 920.

In the embodiment of the disclosure, a control terminal of the reset transistor T11 receives the reset signal RS_n, for example, through the n-th reset signal line. A first terminal of the reset transistor T11 is electrically connected to the first terminal of the capacitor C1. A second terminal of the reset transistor T11 is electrically connected to a reference voltage Vref. In the embodiment of the disclosure, a control terminal of the bias transistor T12 receives the bias signal BS_n, for example, through the n-th bias signal line. A first terminal of the bias transistor T12 is electrically connected to the first terminal of the capacitor C 1. A second terminal of the bias transistor T12 is electrically connected to the reference voltage Vref.

In the embodiment of the disclosure, the constant voltage source circuit 910 may effectively and automatically compensate a leakage current I2 of the tunable component 920 by a compensation current I1(sink current) generated by the source follower circuit 911, and at the same time, a threshold voltage Vth of the drive transistor T1 may also be compensated, so that a bias voltage of the tunable component 920 may be effectively maintained.

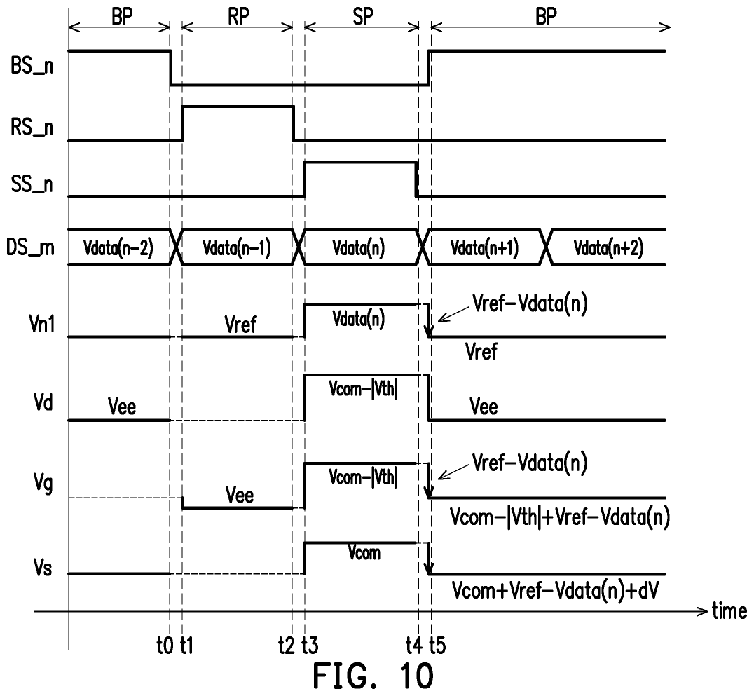

FIG. 10 is a timing diagram of related voltages and signals according to the embodiment of FIG. 9 of the disclosure. Referring to FIG. 9 and FIG. 10, in the embodiment of the disclosure, the M columns of the pixels of the electronic device 900 may respectively and sequentially receive different data signals through the M data signal lines. The N rows of the pixels of the electronic device 900 may respectively and sequentially receive different scan signals through the N scan signal lines. The N rows of the electronic device 900 may respectively and sequentially receive the different bias signals through the N bias signal lines. The N rows of the electronic device 900 may respectively and sequentially receive the different reset signals through the N reset signal lines. Thus, for example, the (m,n)-th pixel may receive a corresponding data signal through the m-th data signal line DL_m in a period specified by the scan signal SS_n through the n-th scan signal line, the bias signal BS_n though the n-th bias signal line and the reset signal RS_n through the n-th reset signal line.

During a reset period RP from time t1 to time t2, the reset signal RS_n is changed from a low voltage level to a high voltage, so that the reset transistors T4, T11 are turned-on. The bias signal BS_n and the scan signal SS_n are maintained at the low voltage level, so that the bias transistors T2, T12, the compensation transistor T3 and the scan transistors T5, T13 are turned-off. Thus, a voltage Vg of the control terminal (i.e. the gate terminal) of the drive transistor T1 is reset to the operation voltage Vee, and a voltage Vnl of the first terminal of the capacitor C1 is reset to the reference voltage Vref, respectively.

During a scan period SP from time t3 to time t4, the scan signal SS_n is changed from the low voltage level to the high voltage, and the data voltage Vdata(n) is stored into the capacitor C1. Moreover, due to the compensation transistor T3 and the scan transistor T5 are turned-on, a voltage Vs of the second terminal (i.e. the source terminal) of the drive transistor T1 is changed to the operation voltage Vcom, the voltage Vg of the control terminal of the drive transistor T1 is changed to the voltage of the operation voltage Vcom minus the threshold voltage lVthl (i.e. Vcom−|Vth|), and a voltage Vd of the first terminal (i.e. the drain terminal) of the drive transistor T1 is also changed to the voltage of the operation voltage Vcom minus the threshold voltage |Vth|. Due to the scan transistors T13 is turned-on, the voltage Vnl of the first terminal of the capacitor C1 is changed to the data voltage Vdata(n). In addition, the data signal DS_m may respectively and sequentially provide different data voltages (e.g. data voltages Vdata(n−2) to Vdata(n+2)) to different rows of the pixels during different periods as shown in FIG. 8.

During a bias period BP after time t5 (and before time t0), the bias signal BS_n is changed from the low voltage level to the high voltage level, so that the bias transistors T2, T12 are turned-on. The reset signal RS_n and the scan signal SS_n are maintained at the low voltage level, so that the compensation transistor T3, the reset transistors T4, T11 and the scan transistors T5, T13 are turned-off. Moreover, the bias transistor T12 may provide the reference voltage Vref to the first terminal of the capacitor C1. Thus, the voltage of the reference voltage Vref minus the data voltage Vdata(n) (i.e. Vref−Vdata(n)) may be transferred to the control terminal of the drive transistor T1 with a capacitive coupling by the capacitor C1, so that the voltage Vg of the control terminal of the drive transistor T1 is changed to the voltage of the operation voltage Vcom minus the threshold voltage 1Vthl, plus the reference voltage Vref, and minus the data voltage Vdata(n) (i.e. Vcom−|Vth|+Vref−Vdata(n)). The voltage Vd of the first terminal of the drive transistor T1 is changed to the operation voltage Vee. The drive transistor T1 is operated as the source follower amplifier, so that the voltage Vs of the drive transistor T1 is changed to the voltage of the operation voltage Vcom plus the reference voltage Vref, minus the data voltage Vdata(n), and plus a voltage dV (i.e. Vcom+Vref−Vdata(n)+dV). The voltage dV is caused by the leakage current I2 to generate the compensation current I1. That is, the bias voltage (Vbias) for the tunable component 920 may be defined as the voltage of the reference voltage Vref minus the data voltage Vdata(n), and plus the voltage dV (i.e. Vref−Vdata(n)+dV).

Therefore, the tunable component 920 may be stably operated in a working state during the bias period BP. When the tunable component 920 occurs the leakage current I2, the bias voltage of the tunable component 920 may rise (Vbias+dV), and the voltage Vs of the second terminal of the drive transistor T1 may also rise. The drive transistor T1 may discharge more current (i.e. the compensation current II) from the tunable component 920 to compensate the leakage current I2 of the tunable component 920, and at the same time, the threshold voltage 1Vthl of the drive transistor T1 can be compensated, so that the bias voltage (Vbias) of the tunable component 920 may be effectively maintained during the bias period BP.

In addition, in the embodiment of the disclosure, the operation voltage Vcom is equal to or higher than the voltage of the operation voltage Vcom plus the reference voltage Vref, and minus the data voltage Vdata(n) (i.e. Vcom+Vref−Vdata(n)), and the voltage of the operation voltage Vcom plus the reference voltage Vref, and minus the data voltage Vdata(n) (i.e. Vcom+Vref−Vdata(n)) is equal to or higher than the operation voltage Vee.

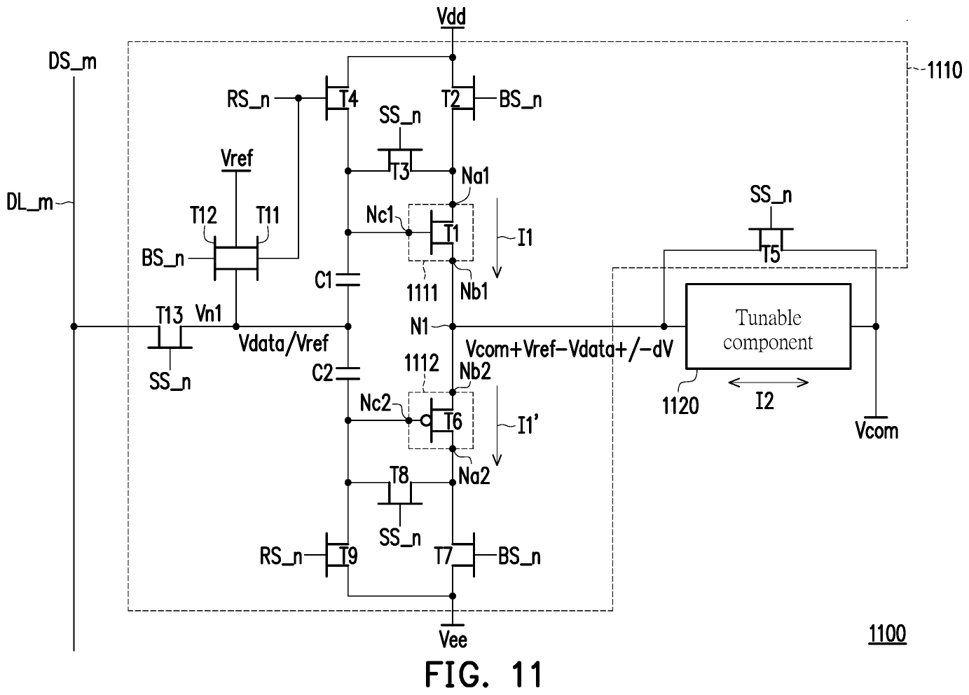

FIG. 11 is a schematic diagram of an electronic device according to an embodiment of the disclosure. Referring to FIG. 11, taking the (m,n)-th pixel as an example, the (m,n)-th pixel of the electronic device 1100 includes a constant voltage source circuit 1110 and a tunable component 1120. The constant voltage source circuit 1110 is electrically connected to a circuit node N1. The constant voltage source circuit 1110 includes source follower circuits 1111, 1112, bias transistors T2, T7, T12, compensation transistors T3, T8, reset transistors T4, T9, T11, scan transistors T5, T13 and capacitors C1, C2. The source follower circuit 1111 includes a drive transistor T1. In the embodiment of the disclosure, the drive transistor T1 is configured to form a first source follower amplifier. In the embodiment of the disclosure, the drive transistor T1 may be the n-type transistor. The source follower circuit 1112 includes a drive transistor T6. In the embodiment of the disclosure, the drive transistor T6 is configured to form a second source follower amplifier. In the embodiment of the disclosure, the drive transistor T6 may be a p-type transistor. The bias transistors T2, T7, T12, the compensation transistors T3, T8, the reset transistors T4, T9, T11 and the scan transistors T5, T13 may also be the n-type transistor, respectively, but the disclosure is not limited thereto.

In the embodiment of the disclosure, the source follower circuit 1111 may include a first terminal Na1, a second terminal Nb1 and a control terminal Nc 1. The control terminal Nc1 of the source follower circuit 1111 is electrically connected to a control terminal (e.g. a gate terminal) of the drive transistor T1. The first terminal Na1 of the source follower circuit 1111 is electrically connected to a first terminal (e.g. a drain terminal) of the drive transistor T1. The second terminal Nb1 of the source follower circuit 1111 is electrically connected to a second terminal (e.g. a source terminal) of the drive transistor T1. In the embodiment of the disclosure, the control terminal Nc1 of the source follower circuit 1111 is electrically connected to the first terminal Na1 of the source follower circuit 1111. The control terminal Nc1 of the source follower circuit 1111 is electrically connected to a data line DL_m (i.e. the m-th data line) through the capacitor C1 and the scan transistor T13. In the embodiment of the disclosure, the reset transistor T11, the bias transistor T12 and the scan transistor T13 are electrically connected to the capacitor C1 and the capacitor C2.

In the embodiment of the disclosure, the source follower circuit 1112 may include a first terminal Na2, a second terminal Nb2 and a control terminal Nc2. The control terminal Nc2 of the source follower circuit 1112 is electrically connected to a control terminal (e.g. a gate terminal) of the drive transistor T6. The first terminal Na2 of the source follower circuit 1112 is electrically connected to a first terminal (e.g. a drain terminal) of the drive transistor T6. The second terminal Nb2 of the source follower circuit 1112 is electrically connected to a second terminal (e.g. a source terminal) of the drive transistor T6. In the embodiment of the disclosure, the control terminal Nc2 of the source follower circuit 1112 is electrically connected to the first terminal Na2 of the source follower circuit 1112. The control terminal Nc2 of the source follower circuit 1112 is electrically connected to the data line DL_m (i.e. the m-th data line) through the capacitor C2, and the scan transistor T13.

In the embodiment of the disclosure, a control terminal of the scan transistor T13 receives a scan signal SS_n, for example, through the n-th scan signal line. A first terminal of the scan transistor T13 is electrically connected to the data line DL_m. A second terminal of the scan transistor T13 is electrically connected to a first terminal of the capacitor C1. The data line DL_m is used to transmit a data signal DS_m with a data voltage to the capacitor C1 through the scan transistor T13. A second terminal of the capacitor C1 is electrically connected to the control terminal Nc1 of the source follower circuit 1111 (i.e. the control terminal of the drive transistor T1). The capacitor C1 is used to couple the data signal DS_m with the data voltage or a reference voltage to the control terminal Nc1 of the source follower circuit 1111. The first terminal Na1 of the source follower circuit 1111 (i.e. the first terminal of the drive transistor T1) is electrically connected to the bias transistor T2 and the compensation transistor T3. The first terminal Na1 of the source follower circuit 1111 is electrically connected to the control terminal Nc1 of the source follower circuit 1111 through the compensation transistor T3. The compensation transistor T3 is electrically connected between the control terminal Nc1 and the first terminal Na1 of the source follower circuit 1111. The second terminal Nb1 of the source follower circuit 1111 (i.e. the second terminal of the drive transistor T1) is electrically connected to the circuit node N1.

In the embodiment of the disclosure, a control terminal of the bias transistor T2 receives a bias signal BS_n, for example, through the n-th bias signal line. A first terminal of the bias transistor T2 is electrically connected to an operation voltage Vdd. A second terminal of the bias transistor T2 is electrically connected to the first terminal Na1 of the source follower circuit 1111. In the embodiment of the disclosure, a control terminal of the compensation transistor T3 receives a scan signal SS_n, for example, through the n-th scan signal line. A first terminal of the compensation transistor T3 is electrically connected to the control terminal Nc1 of the source follower circuit 1111. A second terminal of the compensation transistor T3 is electrically connected to the first terminal Na1 of the source follower circuit 1111.

In the embodiment of the disclosure, a control terminal of the reset transistor T4 receives a reset signal RS_n, for example, through the n-th reset signal line. A first terminal of the reset transistor T4 is electrically connected to the operation voltage Vdd and the first terminal of the bias transistor T2. A second terminal of the reset transistor T4 is electrically connected to the control terminal Nc1 of the source follower circuit 1111 and the first terminal of the compensation transistor T3. In the embodiment of the disclosure, the scan transistor T5 is electrically connected to the circuit node N1, and is electrically connected in parallel to the tunable component 1120. A control terminal of the scan transistor T5 receives the scan signal SS_n, for example, through the n-th scan signal line. A first terminal of the scan transistor T5 is electrically connected to the second terminal Nb1 of the source follower circuit 1111 and a first terminal of the tunable component 1120. A second terminal of the scan transistor T5 is electrically connected to an operation voltage Vcom and a second terminal of the tunable component 1120.

In the embodiment of the disclosure, the second terminal of the scan transistor T13 is further electrically connected to a first terminal of the capacitor C2. The data line DL_m is also used to transmit the data signal DS_m with the data voltage to the capacitor C2 through the scan transistor T13. A second terminal of the capacitor C2 is electrically connected to the control terminal Nc2 of the source follower circuit 1112 (i.e. the control terminal of the drive transistor T6). The capacitor C2 is used to couple the data signal DS_m with the data voltage or the reference voltage to the control terminal Nc2 of the source follower circuit 1112. The first terminal Na2 of the source follower circuit 1112 (i.e. the first terminal of the drive transistor T6) is electrically connected to the bias transistor T7 and the compensation transistor T8. The first terminal Na2 of the source follower circuit 1112 is electrically connected to the control terminal Nc2 of the source follower circuit 1112 through the compensation transistor T8. The compensation transistor T8 is electrically connected between the control terminal Nc2 and the first terminal Na2 of the source follower circuit 1112. The second terminal Nb2 of the source follower circuit 1112 (i.e. the second terminal of the drive transistor T6) is electrically connected to the circuit node N1.

In the embodiment of the disclosure, a control terminal of the bias transistor T7 receives the bias signal BS_n, for example, through the n-th bias signal line. A first terminal of the bias transistor T7 is electrically connected to the first terminal Na2 of the source follower circuit 1112. A second terminal of the bias transistor T7 is electrically connected to an operation voltage Vee. In the embodiment of the disclosure, a control terminal of the compensation transistor T8 receives the scan signal SS_n, for example, through the n-th scan signal line. A first terminal of the compensation transistor T8 is electrically connected to the first terminal Na2 of the source follower circuit 1112. A second terminal of the compensation transistor T8 is electrically connected to the control terminal Nc2 of the source follower circuit 1112.

In the embodiment of the disclosure, a control terminal of the reset transistor T9 receives the reset signal RS_n, for example, through the n-th reset signal line. A first terminal of the reset transistor T9 is electrically connected to the control terminal Nc2 of the source follower circuit 1112 and the second terminal of the compensation transistor T8. A second terminal of the reset transistor T9 is electrically connected to the operation voltage Vee and the second terminal of the bias transistor T7.

In the embodiment of the disclosure, a control terminal of the reset transistor T11 receives the reset signal RS_n, for example, through the n-th reset signal line. A first terminal of the reset transistor T11 is electrically connected to a reference voltage Vref. A second terminal of the reset transistor T11 is electrically connected to the first terminal of the capacitor C1 and the first terminal of the capacitor C2. In the embodiment of the disclosure, a control terminal of the bias transistor T12 receives the bias signal BS_n, for example, through the n-th bias signal line. A first terminal of the bias transistor T12 is electrically connected to the reference voltage Vref. A second terminal of the bias transistor T12 is electrically connected to the first terminal of the capacitor C1 and the first terminal of the capacitor C2.

In the embodiment of the disclosure, the constant voltage source circuit 1110 may effectively and automatically compensate a leakage current I2 of the tunable component 1120 by a compensation current I1 (source current) generated by the source follower circuit 1111 or a compensation current I1′ (sink current) generated by the source follower circuit 1112, and at the same time, a threshold voltage of the drive transistor T1 and another threshold voltage of the drive transistor T6 may also be compensated, so that a bias voltage of the tunable component 1120 may be effectively maintained.

In the embodiment of the disclosure, the constant voltage source circuit 1110 may provide the voltage of the operation voltage Vcom plus the reference voltage Vref, minus the data voltage Vdata, and plus/minus a voltage dV (i.e. Vcom+Vref−Vdata+/−dV). The voltage dV is caused by the leakage current I2 to generate the compensation current I1 or the compensation current I1′. That is, the bias voltage (Vbias) for the tunable component 1120 may be defined as the voltage of the reference voltage Vref minus the data voltage Vdata, and plus/minus the voltage dV (i.e. Vref−Vdata+/−dV).

In addition, in the embodiment of the disclosure, the operation voltage Vdd is equal to or higher than the voltage of the operation voltage Vcom plus the reference voltage Vref, and minus the data voltage Vdata (i.e. Vcom+Vref−Vdata), and the voltage of the operation voltage Vcom plus the reference voltage Vref, and minus the data voltage Vdata (i.e. Vcom+Vref−Vdata) is equal to or higher than the operation voltage Vee. The operation voltage Vdd is higher than the operation voltage Vcom, and the operation voltage Vcom is higher than the operation voltage Vee.

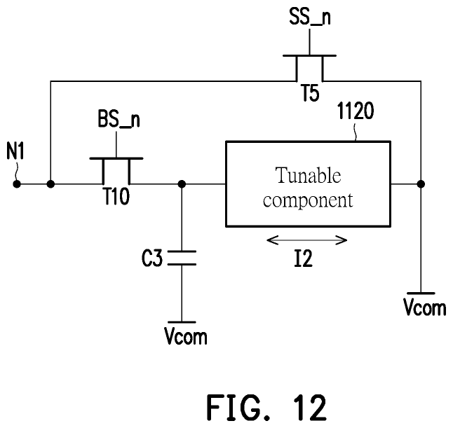

FIG. 12 is a partial circuit schematic diagram of the electronic device according to another embodiment of FIG. 11 of the disclosure. In one embodiment of the disclosure, the constant voltage source circuit 1110 of FIG. 11 may further includes a bias transistor T10 and a capacitor C3, and the bias transistor T10 may be the n-type transistor, but the disclosure is not limited thereto. As shown in FIG. 12, a control terminal of the bias transistor T10 receives the bias signal BS_n. A first terminal of the bias transistor T10 is electrically connected to the circuit node N1 and the first terminal of the scan transistor T5. A second terminal of the bias transistor T10 is electrically connected to the first terminal of the tunable component 1120. A first terminal of the capacitor C3 is electrically connected to the second terminal of the bias transistor T10 and the first terminal of the tunable component 1120. A second terminal of the capacitor C3 is electrically connected to the operation voltage Vcom.

In the embodiment of the disclosure, during the bias period, the bias transistor T10 may be turned-on by the bias signal BS_n to provide the bias voltage to the tunable component 1120, and the bias voltage may also be store into the capacitor C3. Thus, during the reset period and the scan period, the bias transistor T10 may be turned-off by the bias signal BS_n, and the capacitor C3 may continuously provide the pre-stored bias voltage to the tunable component 1120. Therefore, the tunable component 1120 may still be stably driven by the bias voltage during the reset period and the scan period.

In summary, the electronic device of the disclosure is capable of effectively compensating the leakage current of the tunable component without requiring the electronic device to operate at a higher refresh rate nor use a larger storage capacitor.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising:
a tunable component, electrically connected to a circuit node; and
a first source follower circuit, electrically connected to the circuit node, and comprising a first control terminal and a first terminal,
wherein the first control terminal is electrically connected to the first terminal, and the first control terminal is electrically connected to a data line through a first capacitor.

2. The electronic device according to the claim 1, wherein the first source follower circuit comprises a first drive transistor.

3. The electronic device according to the claim 1, further comprising:
a first bias transistor, electrically connected to the first terminal of the first source follower circuit.

4. The electronic device according to the claim 3, wherein the first bias transistor receives a bias signal.

5. The electronic device according to the claim 1, further comprising:
a first compensation transistor, electrically connected between the first control terminal and the first terminal of the first source follower circuit.

6. The electronic device according to the claim 5, wherein the first compensation transistor receives a scan signal.

7. The electronic device according to the claim 1, further comprising:
a first reset transistor, electrically connected to the first control terminal of the first source follower circuit.

8. The electronic device according to the claim 7, wherein the first reset transistor receives a reset signal.

9. The electronic device according to the claim 1, further comprising:
a first scan transistor, electrically connected to the circuit node, and electrically connected in parallel to the tunable component.

10. The electronic device according to the claim 9, wherein the first scan transistor receives a scan signal.

11. The electronic device according to the claim 1, further comprising:
a second reset transistor, electrically connected to the first capacitor.

12. The electronic device according to the claim 1, further comprising:
a second bias transistor, electrically connected to the first capacitor.

13. The electronic device according to the claim 1, further comprising:
a second scan transistor, electrically connected between the first capacitor and the data line.

14. The electronic device according to the claim 1, further comprising:
25 a second source follower circuit, electrically connected to the circuit node, and comprising a second control terminal and a second terminal,
wherein the second control terminal is electrically connected to the second terminal, and the second control terminal is electrically connected to the data line through a second capacitor.

15. The electronic device according to the claim 14, wherein the second source follower circuit comprises a second drive transistor.

16. The electronic device according to the claim 14, further comprising:
a third bias transistor, electrically connected to the second terminal of the second source follower circuit.

17. The electronic device according to the claim 14, further comprising:
a second compensation transistor, electrically connected between the second control terminal and the second terminal of the second source follower circuit.

18. The electronic device according to the claim 14, further comprising:
a second reset transistor, electrically connected to the second control terminal of the second source follower circuit.

19. The electronic device according to the claim 1, further comprising:
a third capacitor, and electrically connected in parallel to the tunable component.

20. The electronic device according to the claim 1, further comprising:
a fourth bias transistor, electrically connected between the circuit node and the tunable component.
